(19) United States
(12) Patent Application Publication
(10) Pub. No.: US 2025/0185205 A1
(43) Pub. Date: Jun. 5, 2025

(54) Liquid Immersion Cooling Platform with an Adjustable Weir and Multifunctional Compute Device Handles

(71) Applicants: RICHARD MARGERISON, Plano, TX (US); TAYLOR MONNIG, Plano, TX (US); RYAN GRAHAM, Plano, TX (US); BRIAN HAUGHT, Plano, TX (US); EDWARD KING, Plano, TX (US); JACOB MERTEL, Plano, TX (US); Modine LLC, Racine, WI (US)

(72) Inventors: Richard Margerison, Plano, TX (US); Taylor Monnig, Plano, TX (US); Ryan Graham, Plano, TX (US); Brian Haught, Plano, TX (US); Edward King, Plano, TX (US); Jacob Mertel, Plano, TX (US); John David Enright, Plano, TX (US)

(21) Appl. No.: 18/844,337

(22) PCT Filed: Apr. 5, 2023
(86) PCT No.: PCT/US2023/017575

§ 371 Date: Sep. 5, 2024

Related U.S. Application Data
(60) Provisional application No. 63/327,737, filed on Apr. 5, 2022.
(60) Provisional application No. 63/327,729, filed on Apr. 5, 2022.

(51) Int. Cl. H05K 7/20

(52) U.S. Cl. CPC H05K 7/20272; H05K 7/20236; H05K 7/20263; H05K 7/203; H05K 7/20327; H05K 7/20772

(57) ABSTRACT

An immersion cooling system and methods for operating the system are described. The system can comprise a vessel which can be configured to hold a thermally conductive dielectric fluid; a computer component which can be configured to be at least partially submerged within the dielectric fluid; and a fluid circulation system which can be configured to draw the dielectric fluid from a sump area of the vessel, pass the dielectric fluid through a filter and deliver the dielectric fluid to a bath area of the vessel. In one example embedment, there can be an adjustable weir between the bath area and the sump area. Multifunctional handles are also described.

### CROSS-REFERENCE TO RELATED APPLICATIONS

This application claims priority to U.S. Application No. 63/327,737 filed Apr. 5, 2022 (docket 121219.0000141) and U.S. Application No. 63/327,729 filed Apr. 5, 2022 (docket 121219.0000138) which applications are incorporated herein by reference.

This application is also related to PCT publication WO2020/102090 filed Nov. 11, 2019 titled “Liquid Immersion Cooling Platform” owned by TMGCore, INC which application is incorporated herein by reference.

### FIELD OF DISCLOSURE

The present disclosure relates to a liquid immersion cooling system adapted to house computing devices, for example, a liquid immersion cooling system including a control system for optimizing the temperature of the system.

The present disclosure also relates to, for example, single phase liquid immersion cooling systems and processes which may include multi-functional compute device handles.

### BACKGROUND AND SUMMARY

Traditional computing and/or server systems utilize air to cool the various components of these systems. Traditional liquid or water cooled computers utilize a flowing liquid to draw heat from computer components but avoid direct contact between the computer components and the liquid itself. The development of electrically non-conductive and/or dielectric fluid enables the use of immersion cooling in which computer components and other electronics may be submerged in a dielectric or electrically non-conductive liquid in order to draw heat directly from the component into the liquid. Immersion cooling can be used to reduce the total energy needed to cool computer components and may also reduce the amount of space and equipment necessary for adequate cooling. Exemplary state of the art two phase immersion cooling systems and processes are described in, for example, U.S. Pat. No. 11,013,144 which is incorporated herein by reference.

The liquid immersion cooling systems are being implemented for various computing needs. As such, it is beneficial to describe an immersion cooling system which can be easily adapted for adjustable transfer mechanism of the dielectric fluid between a bath area and a sump area using an adjustable weir.

Advantageously, the instant application pertains to an exemplary immersion cooling system and methods for operating the system. In one example embodiment, the system can comprise a vessel which can be configured to hold a thermally conductive dielectric fluid; a computer component which can be configured to be at least partially submerged within the dielectric fluid; and a fluid circulation system which can be configured to draw the dielectric fluid from a sump area of the vessel, pass the dielectric fluid through a filter and deliver the dielectric fluid to a bath area of the vessel. In one example embodiment, there can be an adjustable weir between the bath area and the sump area.

In one example embodiment, the adjustable weir can be removably fixed to a wall between the bath area and the sump area. In one example embodiment, the adjustable weir can be fixed to a wall between the bath area and the sump area using screws. In one example embodiment, the system can include an actuator for moving the adjustable weir. In one example embodiment. the system can include a management system for receiving sensor data and instructing the actuator to move the adjustable weir. In one example embodiment. the sensor data can be a fluid level in the bath area or the sump area. In one example embodiment, the sensor data can be a temperature of the dielectric fluid in the bath area or in the sump area. In one example embodiment, the management system can be configured to instruct the actuator to asymmetrically move the adjustable weir wall.

In disclosed embodiments of the invention described below, single phase immersion cooling using oils such as mineral oil are described. Advantageously, the instant application pertains in one embodiment to a cooling system for computing components comprising: a vessel with a bottom. The vessel comprises a central reservoir comprising a heat exchanger for cooling a dielectric fluid. The vessel also comprises a first tank configured to hold one or more computer components at least partially submerged in a dielectric fluid wherein the first tank is on one side of the central reservoir. The vessel comprises a second tank configured to hold one or more computer components at least partially submerged in a dielectric fluid. The second tank is on the opposite side of the central reservoir than the first tank. The vessel comprises a perforated plate which is raised from the bottom of the vessel creating a volume between the bottom of the vessel and the perforated plate which volume comprises (1) a first volume below the central reservoir, (2) a second volume which is below the first tank, and (3) a third volume which is below the second tank. The vessel is configured such that while operating the one or more computer components the dielectric fluid is circulated from the first volume below the central reservoir to each of the second and the third volume, from the second volume to the first tank and from the third volume to the second tank, from the first tank to the central reservoir and from the second tank to the central reservoir, and from the central reservoir to the first volume below the central reservoir. This advantageously provides efficient and effective cooling for the computer components.

In another embodiment, the application pertains to a multifunctional handle for a compute device. The unique, multifunctional handle advantageously allows handling of the compute device without touching the fluid, provides for cable management, acts as a heat sink, and acts as a device identifier.

These and other objects, features and advantages of the exemplary embodiments of the present disclosure will become apparent upon reading the following detailed description of the exemplary embodiments of the present disclosure, when taken in conjunction with the appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 shows a liquid immersion cooling system according to an example embodiment of the present disclosure.

FIG. 2 shows another liquid immersion cooling system according to an example embodiment of the present disclosure.

FIG. 3 shows a top view of the liquid immersion cooling system according to an example embodiment of the present disclosure.

FIG. 4A shows a top view of another liquid immersion cooling system according to an example embodiment of the present disclosure.

FIG. 4B shows a side view of the liquid immersion cooling system according to an example embodiment of the present disclosure.

FIGS. 5A-5L show yet another liquid immersion cooling system according to an example embodiments of the present disclosure.

FIGS. 6A-6F show yet another liquid immersion cooling system according to an example embodiments of the present disclosure.

FIG. 7 shows a representative single phase immersion cooling tank with heat exchanger and weir channels.

FIG. 8 shows the weir channel fluid flow within a representative single phase immersion cooling tank.

FIG. 9 shows the flow pattern for mixing at the bottom of a representative single phase immersion cooling tank in an area below where the servers are located.

FIG. 10 shows a representative unique handle configured to bolt onto, for example, OEM fan locations.

FIG. 11 shows a representative unique handle bolted onto a computing device at the OEM fan locations.

### DETAILED DESCRIPTION

Exemplary embodiments of the invention will now be described in order to illustrate various features of the invention. The embodiments described herein are not intended to be limiting as to the scope of the invention, but rather are intended to provide examples of the components, use, and operation of the invention.

### Immersion Cooling System

In one example embodiment, an immersion cooling system or a vessel can include a bath area, a sump area, an adjustable weir (e.g., in between the bath area and the sump area), a computing device, a robot, a pressure control system and a management system. The vessel can be a pressure controlled tank maintained at the atmospheric pressure (or within a range thereof) which can be cooled using a heat exchanger. The computing device can be immersed in a dielectric fluid in the bath area of the vessel. The computing device can be connected to a network and perform various processing and computing tasks while immersed in the dielectric fluid (or fluid). The vessel can include a lid for accessing the bath area, the computing device and the sump area. The vessel can be fluidly coupled to the pressure control system. The robot can lift the computing device from the bath area of the vessel when the lid is open. The robot can place the lifted computing device in a magazine provided for storage of computing devices or on a vehicle. The robot can also lift a computing device from the magazine (or vehicle) and place it in the place of the computing device that was lifted from the bath area. The robot can be affixed to the vessel, the vehicle or another location. In this example embodiment, the vessel can be a two-phase cooling system. In other example embodiments, the vessel can be a single-phase cooling system, which may or may not have one or more of the above referenced components.

In one example embodiment, a pump can circulate the fluid within the vessel. For example, the pump can draw the dielectric fluid from the sump area, and transfer the fluid into the bath area. The fluid can then flow over the adjustable weir and return to the sump area. In one example embodiment, the height of the adjustable weir can change, e.g., using an actuator and/or instructions provided by the management system. In one example, the depth of the dielectric fluid (or fluid) can change, e.g., as a result of removal or addition of a computing device to the bath area. The depth of the dielectric fluid can also change, e.g., if different computing components are used within the bath area. In this example embodiment, it may be beneficial to adjust the height of the adjustable weir to, e.g., regulate the flow of the dielectric fluid and/or the depth of the dielectric fluid within the bath area.

For example, in one embodiment, less fluid can be desirable in the bath area. In this example, the adjustable weir can be lowered to reduce the depth of the dielectric fluid. As another example, an arrangement of a group of computer devices performing a specific task may generate more heat compared to an average operation of a vessel. In this example, it may be desirable to include more fluid in the tank to compensate for the quick evaporation of the fluid. In this example, the height of the adjustable weir can be raised.

In one example, the management system can be configured with or without software and can be configured to receive any data generated by any of sensors included in the liquid immersion cooling system. In one example, the management system can make an adjustment, provide an alert, and/or take another appropriate action, e.g., based on a sensor reading. For example, the management system can adjust or control the adjustable weir, a heating element, adjust fluid flow or temperature, adjust a pressure, adjust a fluid level, fluid purity and/or any number of other system parameters. Such adjustments are often based on one or more sensed parameters of the liquid immersion cooling system. The sensed parameters can include, e.g., temperature (inside or outside the vessel), pressure, fluid level (in the bath area or the sump area), or power consumption of the system.

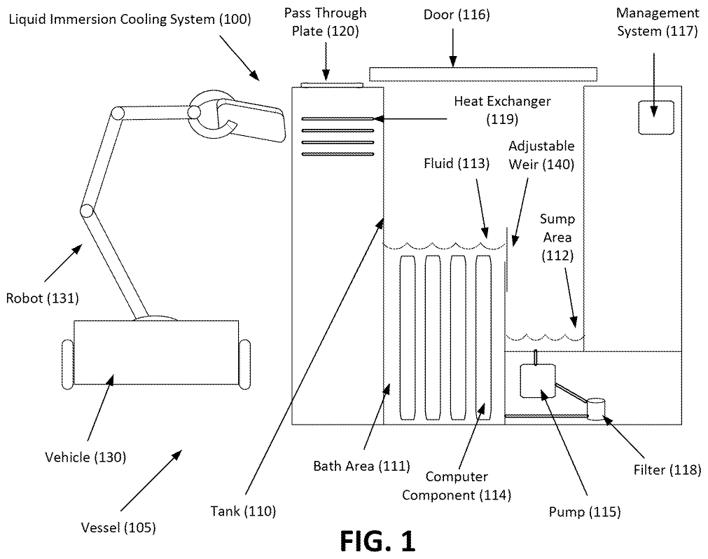

FIG. 1 shows a liquid immersion cooling system 100 according to an example embodiment of the present disclosure. In this example embodiment. the liquid immersion cooling system 100 can include a vessel 105 and a vehicle 130. The vessel 105 can comprise a tank 110, including a bath area 111, a sump area 112, an adjustable weir 140, a fluid 113, a computer component 114, a pump 115, a filter 118, a door 116, a management system 117, a heat exchanger 119 and a pass through plate 120. The computer component 114 can be submersed in the fluid 113. The vehicle 130 can include a robot 131. The robot 131 can lift the computer component 114 when the door 116 is open and place the computer component 114 on the vehicle 130. The adjustable weir 140 can move up and down with instructions provided by the management system 117, e.g., using an actuator. For example, based on a sensor reading of the fluid level in the bath area 111, the management system 117 can instruct the adjustable weir 140 to move up or down to facilitate the transition of the fluid from the bath area 111 to the sump area 112.

In one example embodiment, the immersion cooling system can be a single-phase immersion cooling system. For example, the immersion cooling system can include a tank that holds a volume of dielectric fluid. The tank can also be configured to hold computer components. A pump can draw the dielectric fluid from a sump area and transfer it to the tank. In this example embodiment, the pump can cause the fluid to flow over the adjustable weir into the sump area.

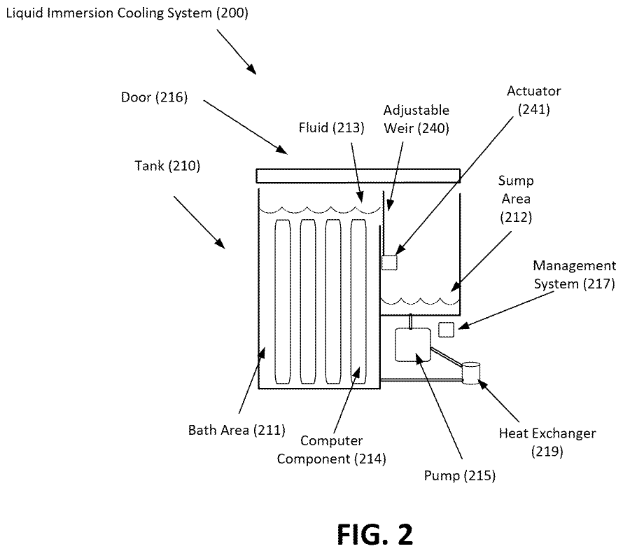

FIG. 2 shows a liquid immersion cooling system 200 according to an example embodiment of the present disclosure. In this example embodiment. the liquid immersion cooling system 200 can include a tank 210, including a bath area 211, a sump area 212, an adjustable weir 240, a fluid 213, a computer component 214, a pump 215, a heat exchanger 219, a door 216, and a management system 217. The computer component 214 can be submersed in the fluid 213. The adjustable weir 240 can move up and/or down with instructions provided by the management system 217, e.g., using an actuator 241. For example, based on a sensor reading of the fluid level in the bath area 211, the management system 217 can instruct the adjustable weir 240 to move up or down to facilitate the transition of the fluid 213 from the bath area 211 to the sump area 212. In this example embodiment, the tank 210 may not be pressure controlled. though in some other example embodiments, the tank can be pressure controlled. In this example embodiment. the door 216 can be removed, a computer component 214 can be lifted out of the tank (or placed back into the tank). The management system 217 can adjust the height of the adjustable weir 240 to maintain the height of the fluid 213 in the tank 210.

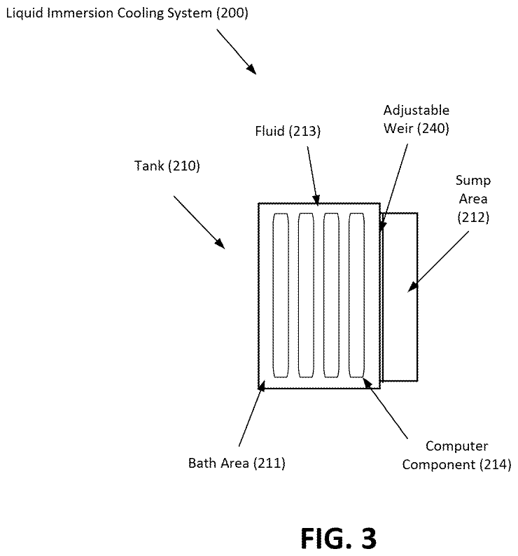

FIG. 3 shows a top view of the liquid immersion cooling system 200 according to an example embodiment of the present disclosure. In this example embodiment, the sump area 212 is next to the bath area 211, and the adjustable weir 240 is between the bath area 211 and the sump area 212.

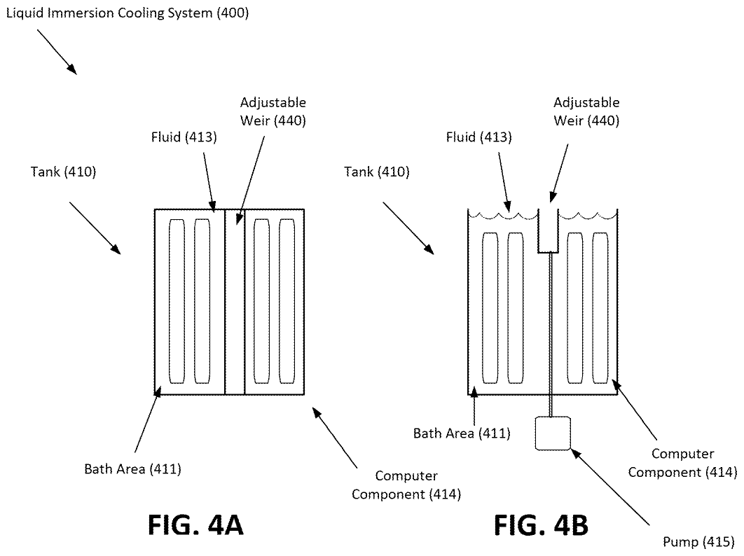

FIG. 4A shows a top view of the liquid immersion cooling system 400 according to an example embodiment of the present disclosure. In this example embodiment, the adjustable weir 440 is a channel in the middle of the bath area 411. The adjustable weir 440 or the channel can move up or down to facilitate fluid transfer outside of the tank 410. FIG. 4B shows a side view of the liquid immersion cooling system 400 according to an example embodiment of the present disclosure. In this example, the adjustable weir 440 is connected to a pump 415 through, e.g., a flexible pipe. The adjustable weir 440 can move up or down so that it is at the appropriate level with the fluid 413.

In one example embodiment, the adjustable weir can be coupled to a motor or actuator which can facilitate movement of the weir. In other example embodiments, the weir can removably fixed to the body of the bath area or the tank, e.g., using screws, and can be moved up or down upon, e.g., removing the screws to adjust the height of the weir.

In one example embodiment. the management system can include a module for estimating an appropriate position for the weir. For example, the module can receive sensor data such as the fluid level in the bath area or the sump area, the temperature of the fluid or the computing components, outside temperature, fluid viscosity, or other sensor data, and based on the sensor data, can determine an appropriate height for the fluid in the bath area. Subsequently, the management system can instruct a motor or an actuator to adjust the weir height accordingly. For example, if due to removal of one or more computing components the fluid level has dropped below an acceptable level, the management system can instruct the actuator to lower the adjustable weir. On the other hand, if due to addition of a computer component, the fluid level in the sump area has increased, the management system can move the weir higher so that the bath area can hold additional fluid.

In one example embodiment, the actuator can move the weir asymmetrically (e.g., moving one side more or less than the other side). Asymmetrical movement of the adjustable weir can result in, e.g., a tilted weir. Asymmetrical movement of the weir can facilitate asymmetric fluid transfer from the bath area. For example, if one side of the weir is lower than the other side, more fluid from the lower side can transfer outside of the bath area. The asymmetric movement of the weir can be beneficial when, e.g., one side of the tank is warmer than the other side, and therefore, it can be desirable for the fluid to transfer from the warmer or colder side faster than the other side.

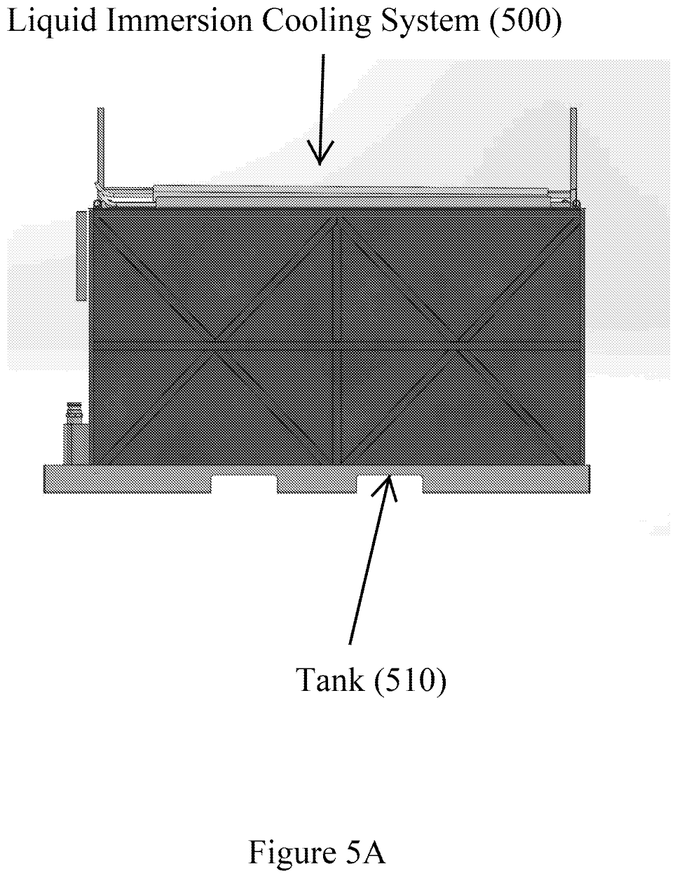

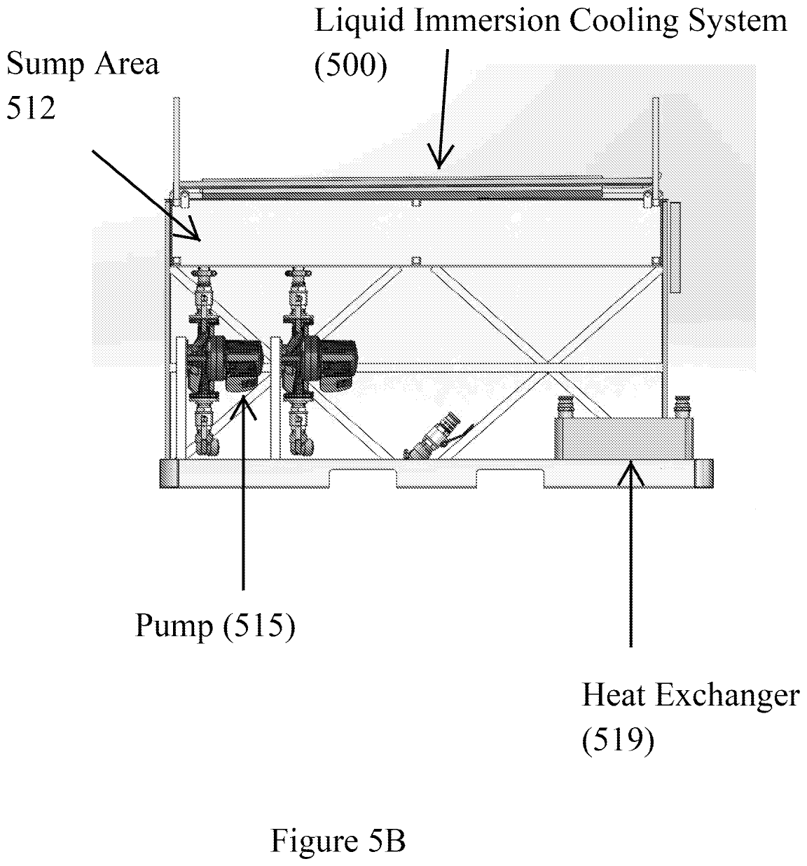

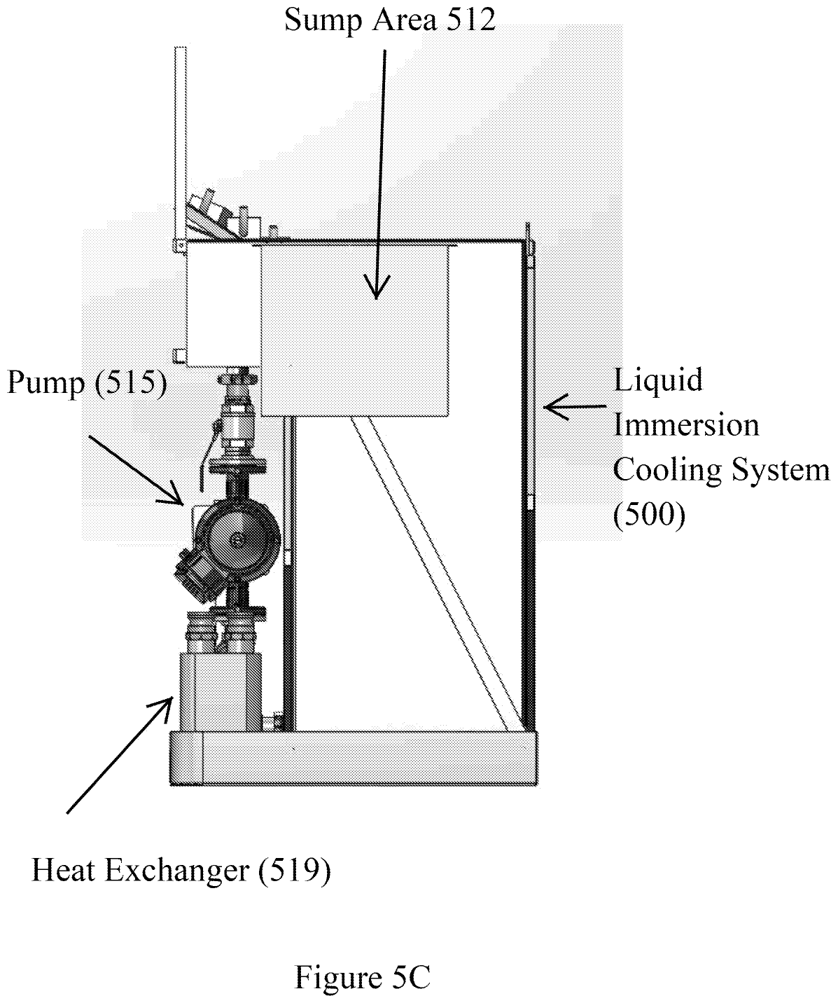

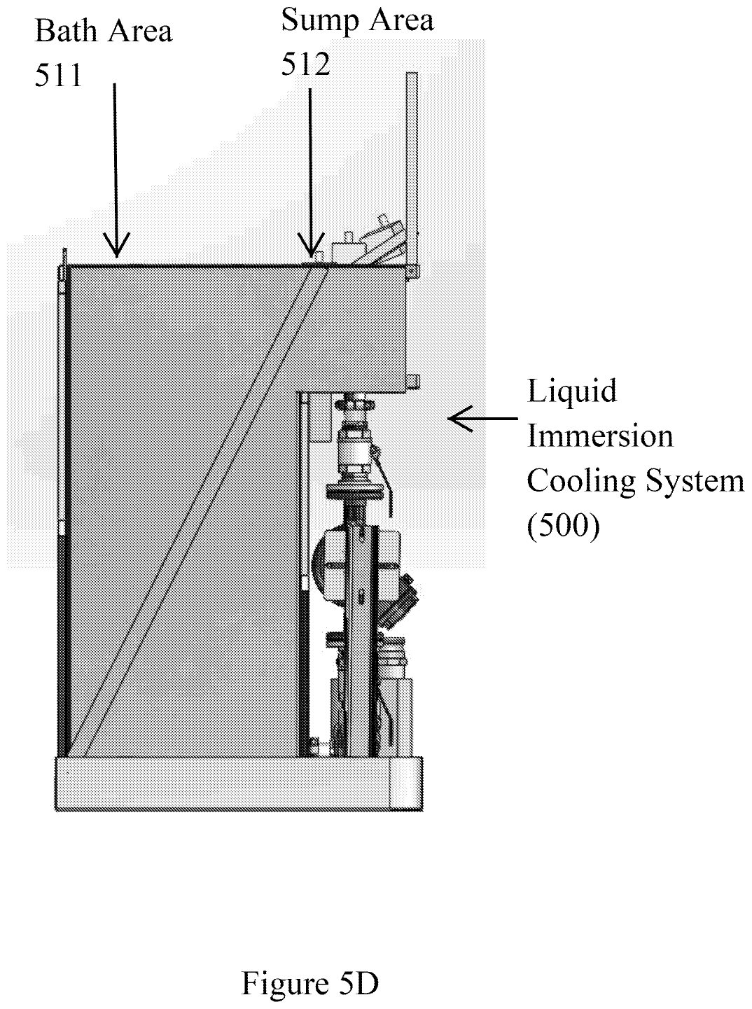

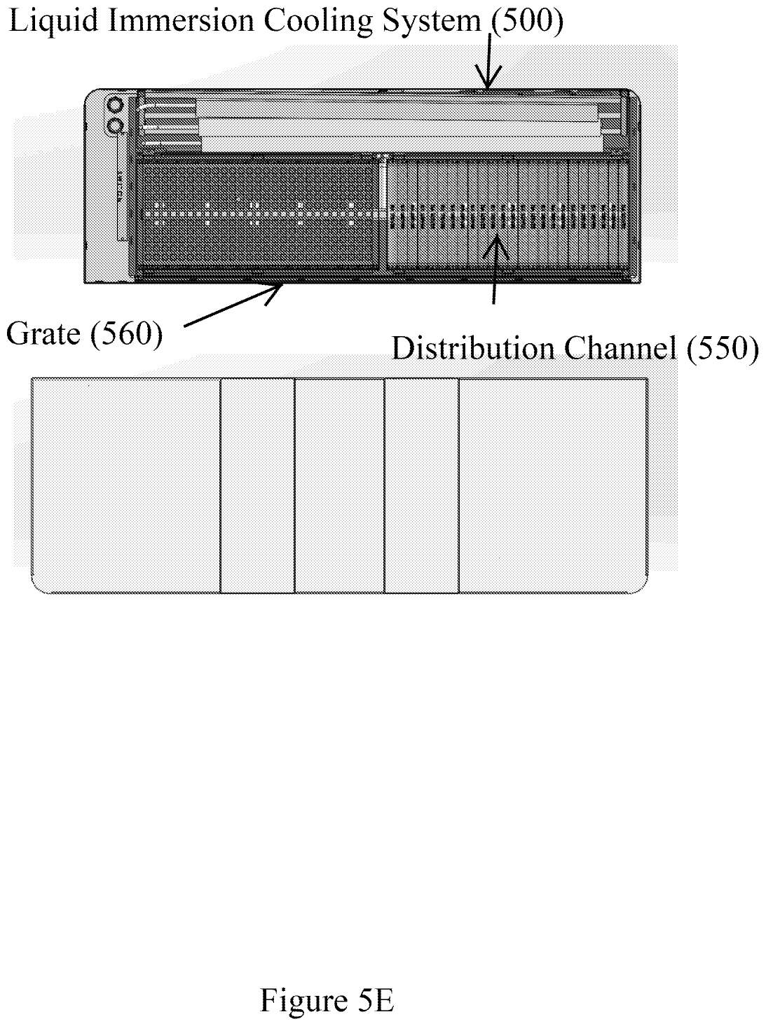

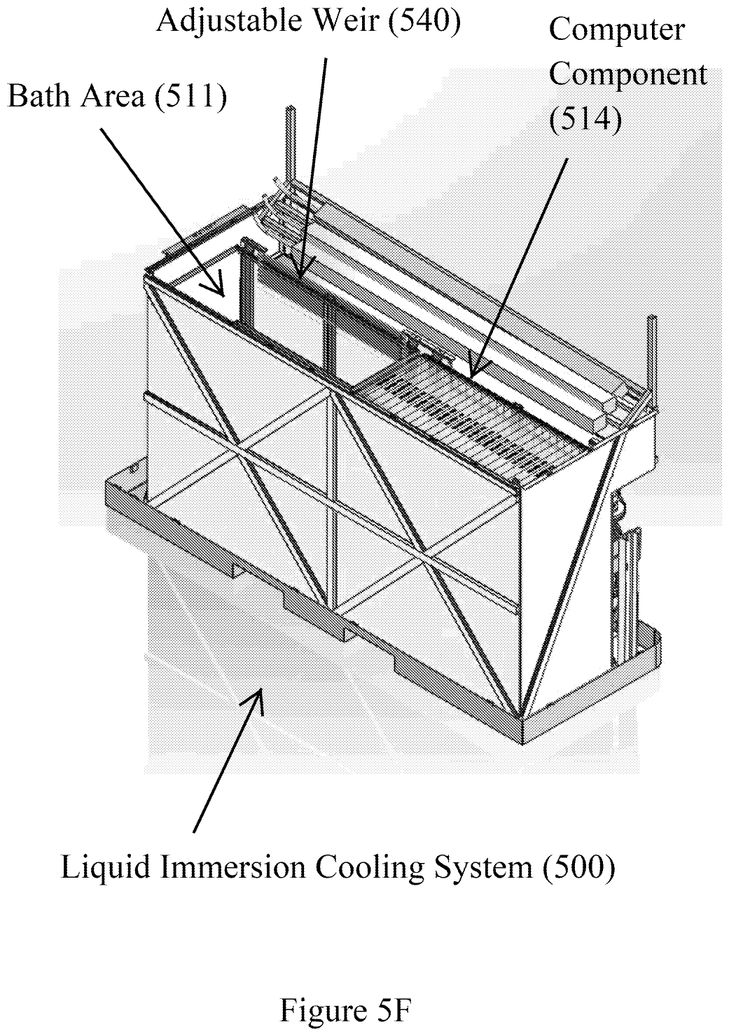

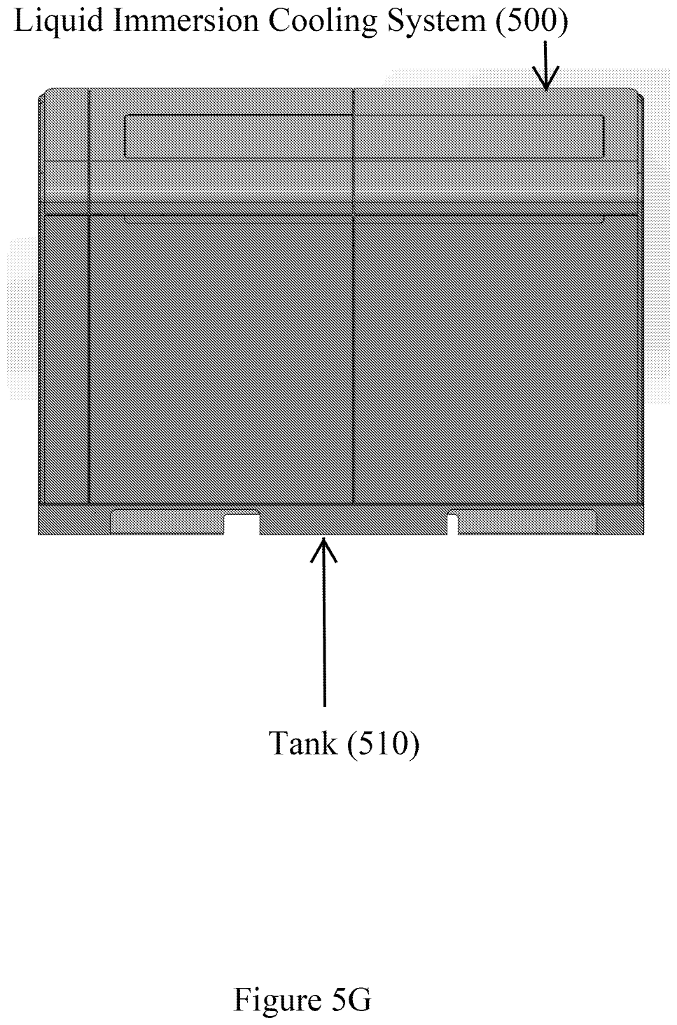

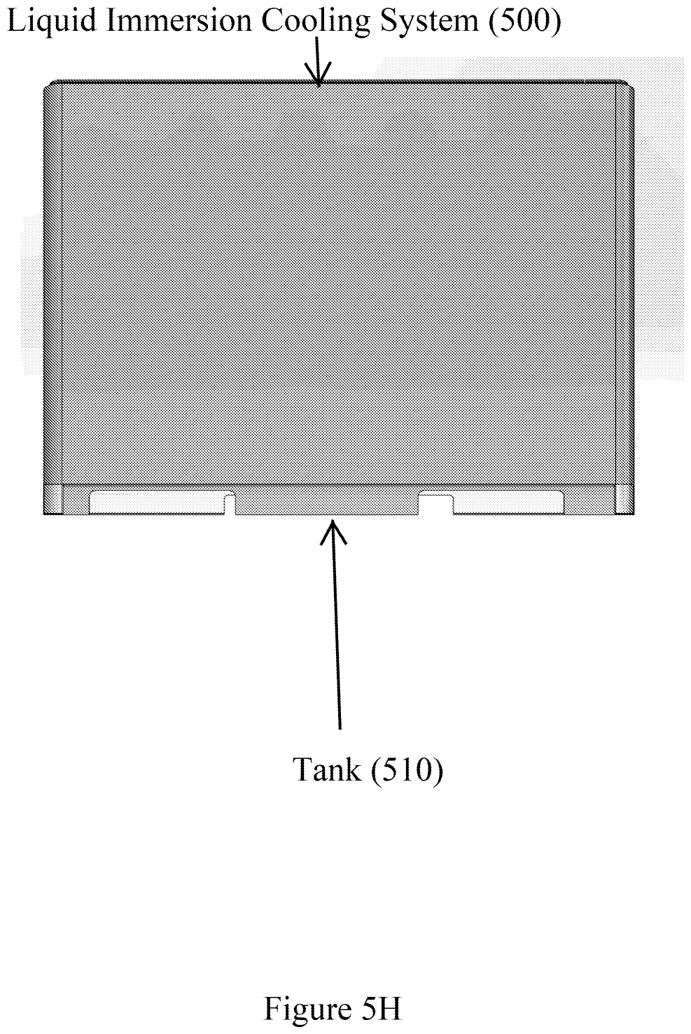

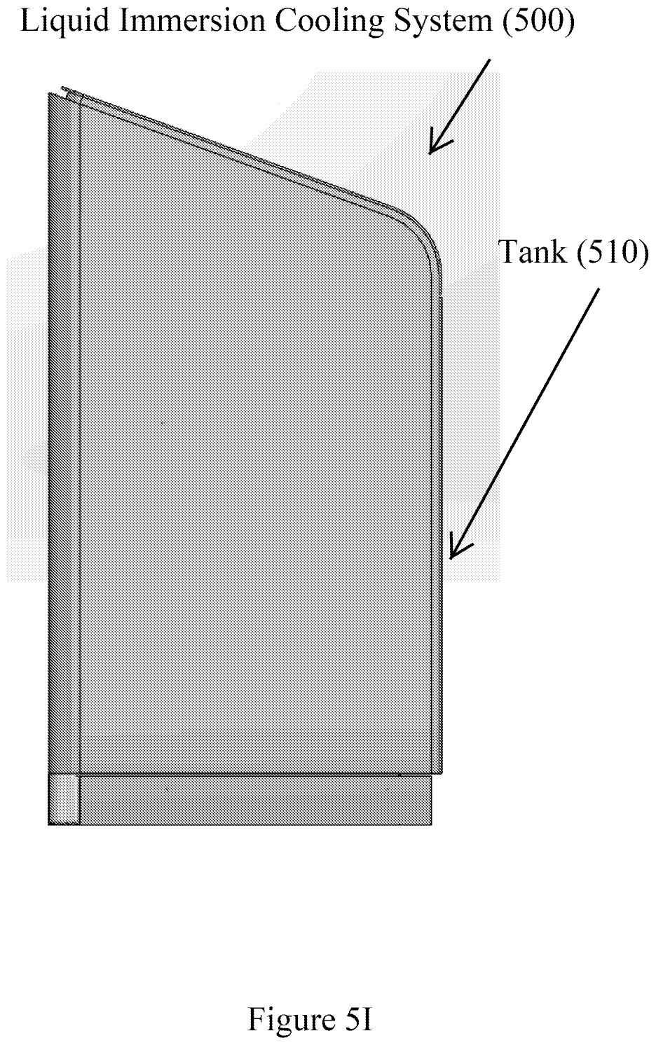

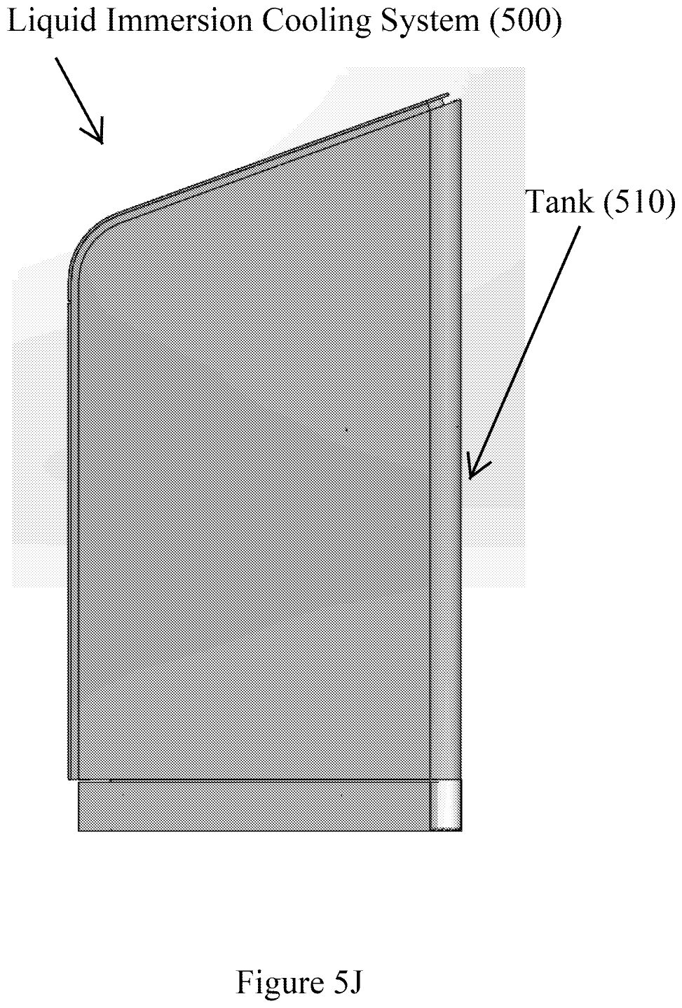

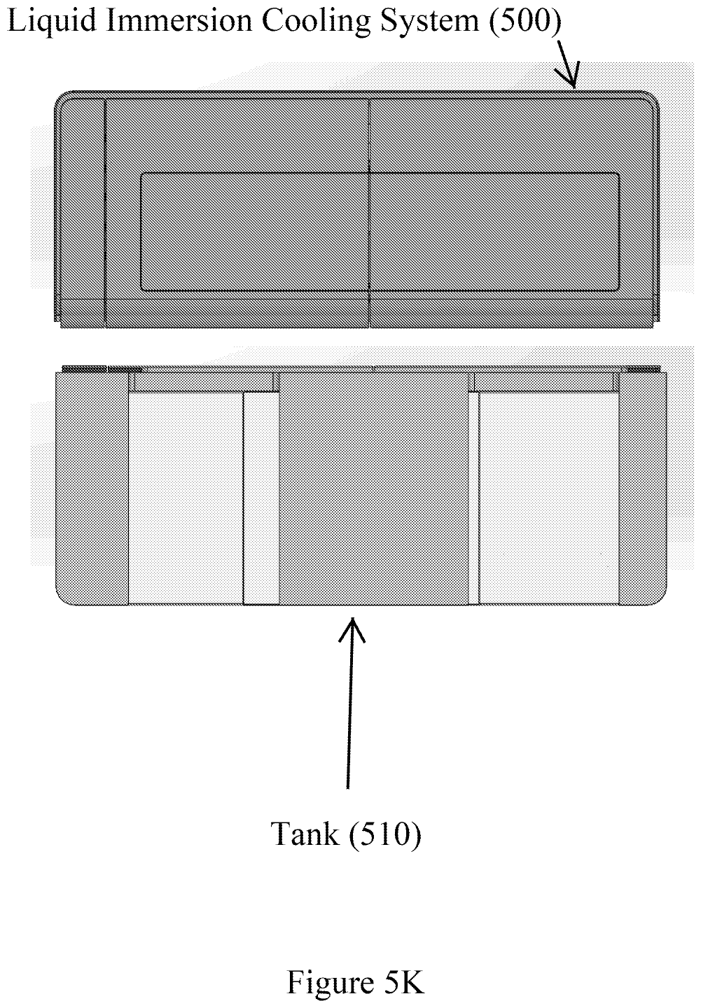

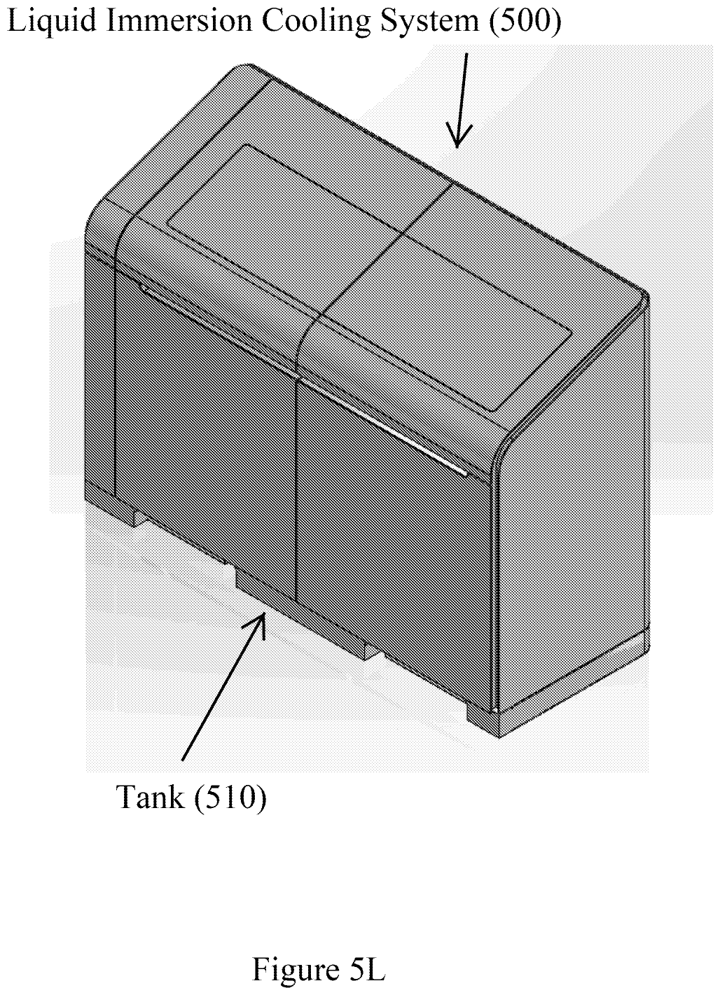

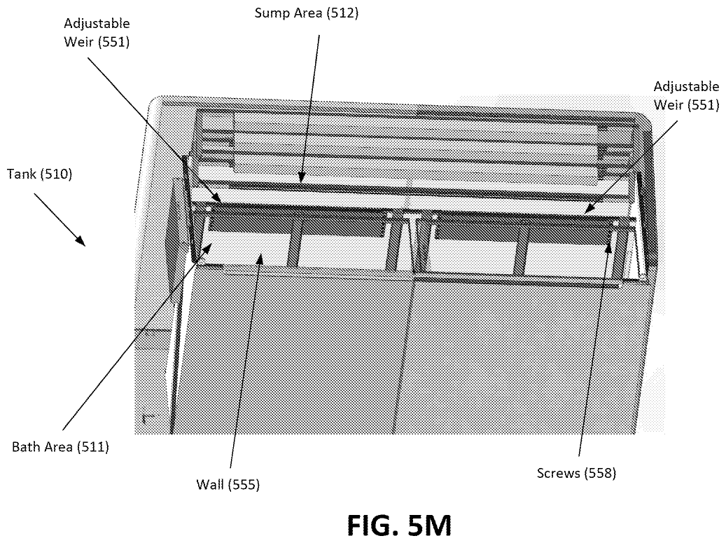

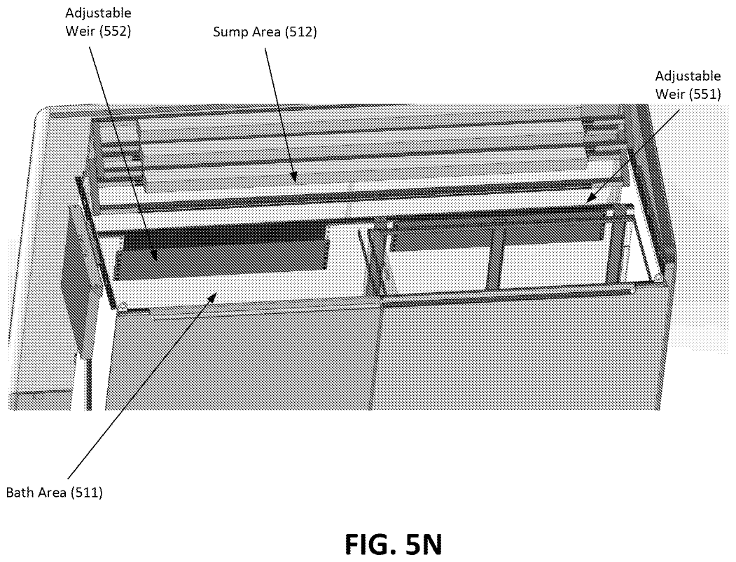

FIGS. 5A-5L show a liquid immersion cooling system 500 according to an example embodiments of the present disclosure. In this exemplary embodiment, the liquid immersion cooling system 500 can include a tank 510, a bath area 511, a sump area 512, a pump 515, a heat exchanger 519 and a computer component 514. At the bottom of the bath area 511, there can be a distribution channel which allows for the dielectric fluid to be distributed in the bath area 511. For example, the pump 515 can draw the fluid from the sump area and distribute it through the distribution channel 550 in the bath area 511. Over the distribution channel 550, there can be a grate. The computer component 514 can be placed over the grate 560, e.g., using a rack system. In this example embodiment, the sump area 512 can be over the pump 515 and the heat exchanger 519. The heat exchanger can receive heated dielectric fluid from the tank and cool the dielectric fluid using another fluid, e.g., water. The heat exchanger can receive cool water and discharge the heated water, which can be cooled at a separate facility or location. The adjustable weir 540 can be between the bath area 511 and the sump area 512. In this example, the adjustable weir can be moved up and down (or even asymmetrically moved up and down) to facilitate the transfer of the fluid from the bath area 511 to the sump area 512.

FIGS. 5M and 5N show exemplary adjustable weirs which can be removably attached to a wall between a bath area and a sump area. In this example, the adjustable weirs 551 are affixed using screws 558 to the wall 555, which is between the bath area 511 and the sump area 512. In FIG. 5N, the weir 552 has been moved lower than the weir 551. In this example, the dielectric fluid can exit the bath area 511 from the left side of the bath area.

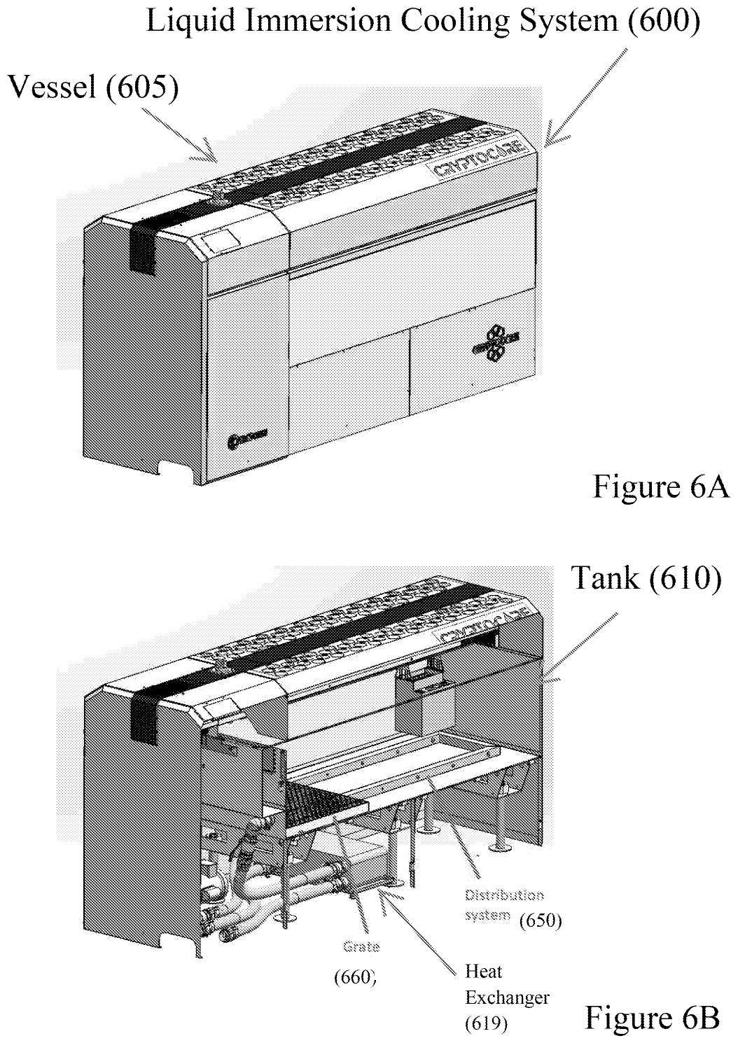

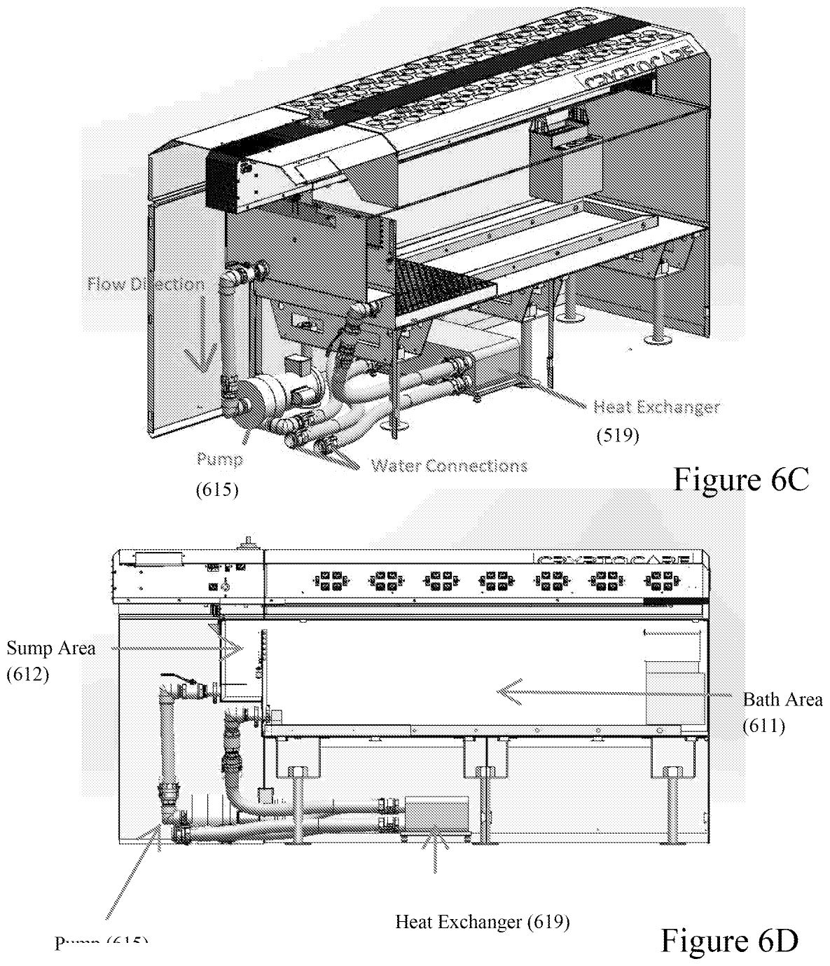

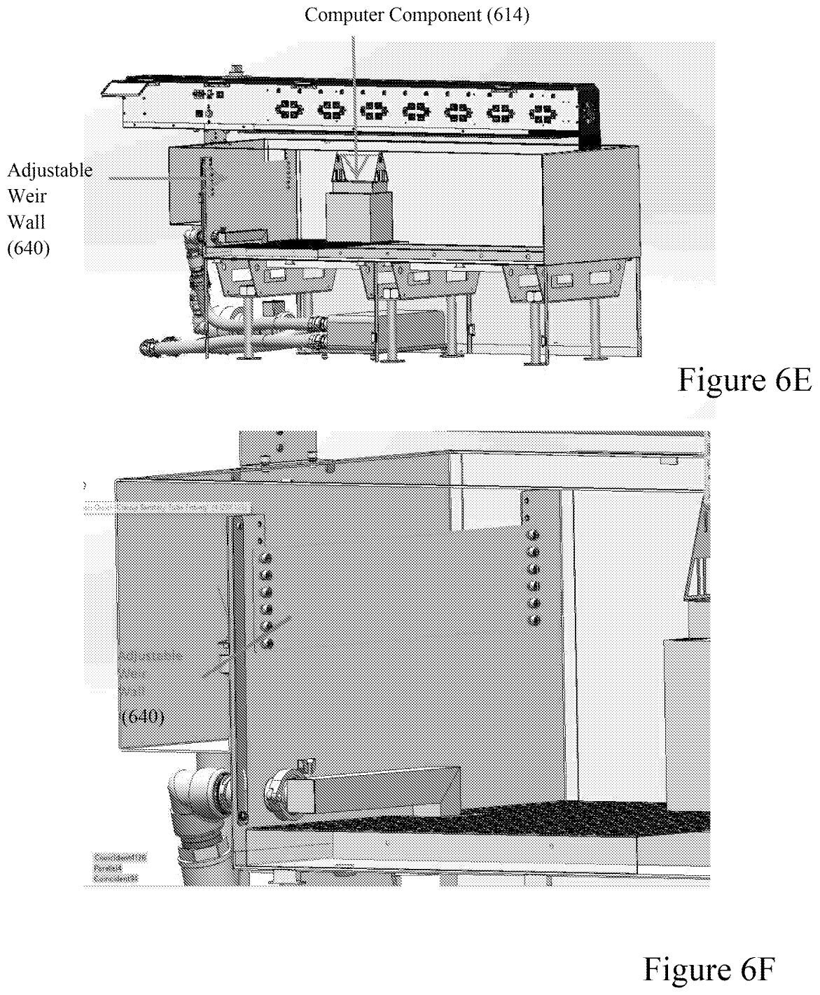

FIGS. 6A-6F show a liquid immersion cooling system 600 according to an example embodiments of the present disclosure. In this exemplary embodiment, the liquid immersion cooling system 600 can include a vessel 605, a tank 610, a bath area 611, a sump area 612, a pump 615, a heat exchanger 619 and a computer component 614. At the bottom of the bath area 611, there can be a distribution system which allows for the fluid to be distributed in the bath area 611. There can be a grate 660 over the distribution system 650. In this example embodiment, there can also be an adjustable weir wall 640 between the bath area 611 and the sump area 612. In this example embodiment, the adjustable weir wall 640 can be removably fixed (e.g., using screws) to a wall between the bath area 611 and the sump area 612. The screws can be removed and the adjustable weir wall can be moved up or down so that a desired amount of fluid is delivered out of the bath area 611.

### Single Phase Systems and Methods

In one embodiment the present application pertains to a single phase immersion system that may comprise a vessel configured to comprise a volume of thermally conductive dielectric fluid, e.g., mineral oil, in a liquid phase. A rack may be configured to hold one or more computer components such that the one or more computer components may be at least partially submerged within the liquid of the dielectric fluid. A heat exchanger may be employed for cooling.

In another embodiment for single phase immersion the system has two separate tanks for server placement with a center reservoir. Surrounding each tank is a weir channel that forces collection of the fluid to the center reservoir. Fluid collects in the center reservoir and is pumped into a two-sided heat exchanger, one side for fluid and one side for house cooling water. The house water and plate exchanger work together to remove heat from the fluid. From the heat exchanger, the fluid is forced into the bottom of each tank and mixed in an area below the servers and forced to flow from the bottom of each tank to the top of the tank and resultantly into the weir channels.

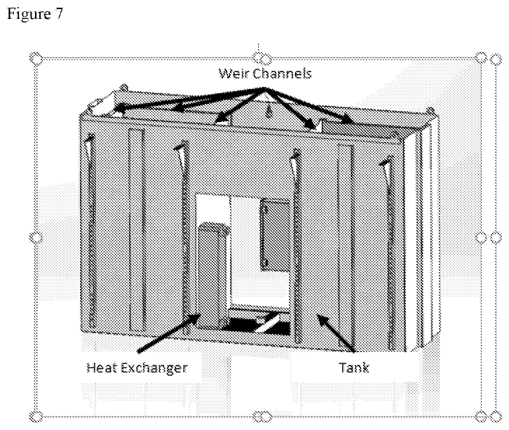

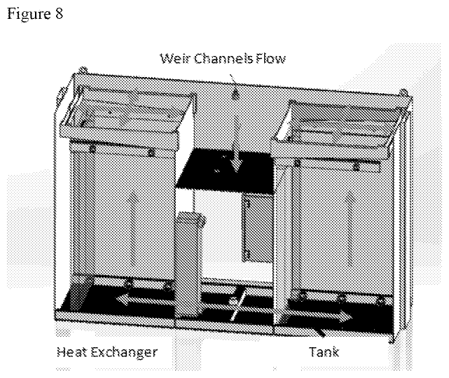

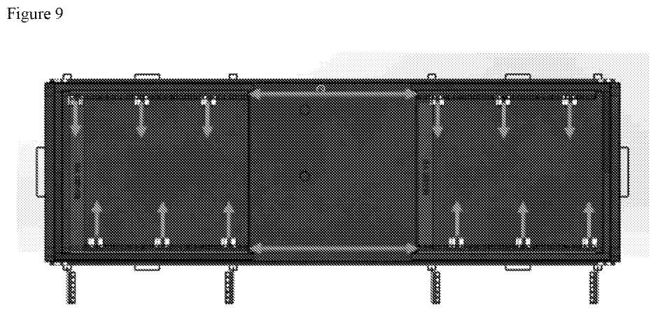

FIGS. 7 and 8 show a representative single phase immersion cooling tank comprising a heat exchanger and a plurality of weirs. As shown in FIGS. 7-8 there are two separate tanks for server placement with a center reservoir. Surrounding each tank is a weir channel that forces collection of the fluid to the center reservoir. Fluid collects in the center reservoir and is pumped into a two-sided heat exchanger, one side for fluid and one side for house cooling water. The house water and plate exchanger work together to remove heat from the fluid. From the heat exchanger, the fluid is forced into the bottom of each tank and mixed in an area below the servers as shown in FIG. 9. From the area below the servers the fluid is forced to flow from the bottom of each tank to the top of the tank and resultantly into the weir channels.

In this configuration a perforated plate is raised from the bottom of the vessel creating a volume between the bottom of the vessel and the perforated plate. This volume comprises (1) a first volume below the central reservoir, (2) a second volume which is below the first tank, and (3) a third volume which is below the second tank. The vessel is configured such that while operating the one or more computer components the dielectric fluid is circulated from the first volume below the central reservoir to each of the second and the third volume. from the second volume to the first tank and from the third volume to the second tank. from the first tank to the central reservoir and from the second tank to the central reservoir, and from the central reservoir to the first volume below the central reservoir. Since the pump is typically located centrally the upward flow rate through the perforated plate is not uniform and decreases with distance from the pump. Pumping the fluid non-uniformly through the plurality of holes advantageously promotes cooling efficiency.

The vessel may be configured such that while operating the one or more computer components the dielectric fluid is circulated from the first volume below the central reservoir to each of the second and the third volume, from the second volume to the first tank and from the third volume to the second tank, from the first tank to the central reservoir and from the second tank to the central reservoir, and from the central reservoir to the first volume below the central reservoir. Such a flow pattern is shown in FIGS. 8 and 9.

In some embodiments a multifunctional handle is employed with the compute devices to be cooled. The handle advantageously allows handling of the compute devices without touching the fluid, provides for cable management, acts as a heat sink, and/or acts as a device identifier.

### Multifunctional Handle for Computing Devices

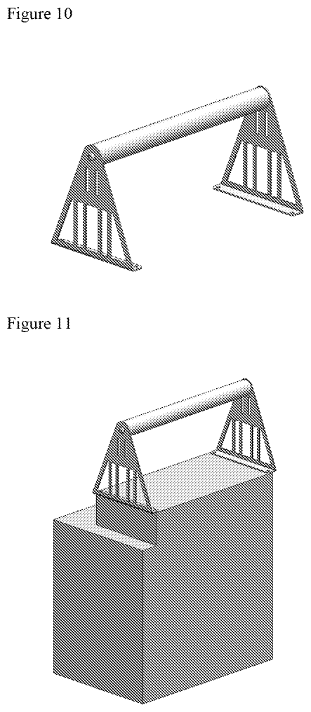

FIG. 10 shows a representative unique handle configured to bolt onto, for example, OEM fan locations. FIG. 11 shows a representative unique handle bolted onto a computing device at the OEM fan locations. Such handles may be useful in single phase or two phase immersion cooling systems used in, for example, mining cryptocurrency or cooling servers. Advantageously, by configuring the handle to be fastened by, for example, bolts or screws into OEM fan location the handle may be advantageously fastened without drilling or time involved for crating new mounting points.

The handle generally comprises a bar or other gripping mechanism with opposing brackets configured to mount to the computing device to be cooled. The handle height from the mounting point to the bar or other mechanism for gripping may vary depending upon the application. Generally, the height is sufficient such that the user does not have to touch the immersion fluid when removing the device. In some embodiments the handle may be made such that the height is adjustable by, for example, adding an additional bracket and/or having a telescoping assembly with a locking mechanism.

In some embodiments, the side mounting brackets may have one or more openings for to promote the flow of dielectric fluid and enhance cooling. Such openings may vary in size and shape depending upon the application. As shown in FIGS. 10 and 11 the openings are slits although a plurality of other shapes may be employed also. The slits or other openings may also be used for cable management within the immersion tank. That is, system power and/or network cables may be affixed to the handle using ties, wires, Velcro, or other suitable fasteners extending through and around the openings and cables.

The handle may also be employed as a heat sink to assist in cooling the computing device. That is, heat from the dielectric fluid may be transferred via conduction to the side mounting brackets and then to the bar or other gripping device and to the air to which the bar or other gripping device is exposed.

The bar or other gripping device and the mounting brackets may be comprised of the same or different material which material may vary depending upon the application. Suitable materials include, for example, metals such as aluminum, copper, steel, and mixtures thereof.

Advantageously, the portion of the handle not exposed to fluid, e.g., bar or other gripping device, may comprise an etching, a sticker, or other identifying characteristic to identify the computer device to which it is attached. In this manner, adhesive stickers or other materials do not potentially contaminate the dielectric fluid.

### Embodiments

1. A cooling system for computing components comprising:

a vessel with a bottom wherein the vessel comprises:

a central reservoir comprising a heat exchanger for cooling a dielectric fluid;

a first tank configured to hold one or more computer components at least partially submerged in a dielectric fluid wherein the first tank is on one side of the central reservoir;

a second tank configured to hold one or more computer components at least partially submerged in a dielectric fluid wherein the second tank is on the opposite side of the central reservoir than the first tank;

a perforated plate which is raised from the bottom of the vessel creating a volume between the bottom of the vessel and the perforated plate which volume comprises (1) a first volume below the central reservoir, (2) a second volume which is below the first tank, and (3) a third volume which is below the second tank;

wherein the vessel is configured such that while operating the one or more computer components the dielectric fluid is circulated from the first volume below the central reservoir to each of the second and the third volume, from the second volume to the first tank and from the third volume to the second tank, from the first tank to the central reservoir and from the second tank to the central reservoir, and from the central reservoir to the first volume below the central reservoir.
2. The cooling system of embodiment 1 wherein the vessel comprises weir channels for circulating the dielectric fluid.
3. The cooling system of embodiment 1 which further comprises a rack for the one or more computer components.
4. The cooling system of embodiment 1 wherein the rack comprises a handle configured for removing the rack from the system without handling dielectric fluid.
5. The cooling system of embodiment 1 wherein the rack comprises a handle configured as a heat sink for removing heat from the system.
6. The cooling system of embodiment 1 wherein the rack comprises a handle configured to assist in managing one or more cables in the system.

In the preceding specification, various embodiments have been described with references to the accompanying drawings. It will, however, be evident that various modifications and changes may be made thereto, and additional embodiments may be implemented, without departing from the broader scope of the invention as set forth in the claims that follow. The specification and drawings are accordingly to be regarded as an illustrative rather than restrictive sense.

What is claimed is:

1. A system comprising:
a vessel configured to hold a thermally conductive dielectric fluid;
a computer component configured to be at least partially submerged within the dielectric fluid; and
a fluid circulation system configured to draw the dielectric fluid from a sump area of the vessel, pass the dielectric fluid through a filter and deliver the dielectric fluid to a bath area of the vessel;
wherein there is an adjustable weir between the bath area and the sump area.

2. The system of claim 1, wherein the adjustable weir is removably fixed to a wall between the bath area and the sump area.

3. The system of claim 1, wherein the adjustable weir is fixed to a wall between the bath area and the sump area using screws.

4. The system of claim 1, further comprising an actuator for moving the adjustable weir.

5. The system of claim 2, further comprising a management system for receiving sensor data and instructing the actuator to move the adjustable weir.

6. The system of claim 5, wherein the sensor data is a fluid level in the bath area or the sump area.

7. The system of claim 5, wherein the sensor data is a temperature of the dielectric fluid in the bath area or in the sump area.

8. The system of claim 5, wherein the management system is configured to instruct the actuator to asymmetrically move the adjustable weir wall.

9. A cooling system for computing components comprising:
a vessel with a bottom wherein the vessel comprises:
a central reservoir comprising a heat exchanger for cooling a dielectric fluid;
a first tank configured to hold one or more computer components at least partially submerged in a dielectric fluid wherein the first tank is on one side of the central reservoir;
a second tank configured to hold one or more computer components at least partially submerged in a dielectric fluid wherein the second tank is on the opposite side of the central reservoir than the first tank;
a perforated plate which is raised from the bottom of the vessel creating a volume between the bottom of the vessel and the perforated plate which volume comprises (1) a first volume below the central reservoir, (2) a second volume which is below the first tank, and (3) a third volume which is below the second tank;
wherein the vessel is configured such that while operating the one or more computer components the dielectric fluid is circulated from the first volume below the central reservoir to each of the second and the third volume, from the second volume to the first tank and from the third volume to the second tank, from the first tank to the central reservoir and from the second tank to the central reservoir, and from the central reservoir to the first volume below the central reservoir.

10. The cooling system of claim 9 wherein the vessel comprises weir channels for circulating the dielectric fluid.

11. The cooling system of claim 9 which further comprises a rack for the one or more computer components.

12. The cooling system of claim 9 wherein the rack comprises a handle configured for removing the rack from the system without handling dielectric fluid.

13. The cooling system of claim 9 wherein the rack comprises a handle configured as a heat sink for removing heat from the system.

14. The cooling system of claim 9 wherein the rack comprises a handle configured to assist in managing one or more cables in the system.

15. A handle suitable for use with single phase or two phase immersion computing devices comprising:
a bar; and
one or more mounting brackets configured to be attached to a computing device to be immersed in dielectric fluid.

16. The handle of claim 15 wherein the one or more mounting brackets comprise a plurality of openings configured to facilitate dielectric fluid flow.

17. The handle of claim 15 wherein the bar and one or more mounting brackets are configured as a heat sink for removing heat from the system.

18. The handle of claim 15 wherein the one or more mounting brackets are configured to assist in managing one or more cables in the system.
